(19) United States
(12) Patent Application Publication
(10) Pub. No.: US 2026/0082905 A1
(43) Pub. Date: Mar. 19, 2026

(54) THIN-FILM RESISTOR (TFR) DEVICE WITH IMPROVED TFR ELEMENT

(71) Applicant: Microchip Technology Incorporated, Chandler, AZ (US)

(72) Inventor: Yaojian Leng, Vancouver, WA (US)

(73) Assignee: Microchip Technology Incorporated, Chandler, AZ (US)

(21) Appl. No.: 19/014,052

(22) Filed: Jan. 8, 2025

Related U.S. Application Data
(60) Provisional application No. 63/696,029, filed on Sep. 18, 2024.

(51) Int. Cl. H01L 23/522; H01C 7/00; H01C 17/075; H01L 21/768; H10D 1/47

(52) U.S. Cl. CPC H10W 20/498; H01C 7/006; H01C 17/075; H10D 1/474; H10W 20/037; H10W 20/083; H10W 20/089

(57) ABSTRACT

A method includes forming first and second TFR contacts spaced apart in a dielectric region, forming a dielectric barrier layer over the TFR contacts, and removing a region of the dielectric barrier layer to define an opening defining a pair of lateral edges of the dielectric barrier layer extending between the first and second TFR contacts. An etch is performed through the opening to define a TFR cavity including respective undercut cavity regions extending laterally below the dielectric barrier layer near each of the lateral edges. A TFR material is deposited in the TFR cavity to define a TFR element layer including (a) a TFR element base defining a pair of end edges adjacent the first and second TFR contacts, and a pair of side edges extending between the end edges; and (b) a pair of TFR element end ridges extending upwardly from the end edges of TFR element base.

### RELATED APPLICATION

This application claims priority to commonly owned United States Provisional Patent Application No. 63/696,029 filed Sep. 18, 2024, the entire contents of which are hereby incorporated by reference for all purposes.

### TECHNICAL FIELD

The present disclosure relates to thin-film resistors (TFRs), in particular to a TFR with an improved TFR element, for example including a TFR element free of vertical side ridges.

### BACKGROUND

With more features being packed into individual semiconductor chips, there is an increased need to fit large numbers of passive components, such as resistors, into the circuits. Some resistors can be created through ion implantation and diffusion, such as poly resistors. However, such resistors typically have high variations in resistance value, and may also have resistance values that change drastically as a function of temperature. A technique for constructing integrated resistors, called Thin-Film Resistors (TFRs), typically improves integrated resistor performance. TFRs are often formed from silicon-chromium (SiCr), silicon-silicon carbide-chromium (SiCCr), TaN, nickel-chromium (NiCr), aluminum-doped nickel-chromium (AlNiCr), or titanium-nickel-chromium (TiNiCr), for example.

The fabrication of conventional TFR devices typically requires three or more added mask layers, with reference to a background fabrication process for the relevant IC device. For example, one common fabrication process includes a first added mask layer for forming a pair of TFR heads, a second added mask layer for forming a TFR element connected between the TFR heads, and a third added mask layer for forming TFR vias providing contact to the TFR heads.

In another conventional process, a TFR element connected between a pair of TFR contacts is formed by a damascene process, wherein the resulting TFR element has a cup-or tray-shaped structure including a planar base portion and vertical ridges extending upwardly from the perimeter edges of the base portion. The vertical ridges typically include (a) vertical ridges extending upwardly from opposing ends of the base portion adjacent the pair of TFR contacts, referred to herein as “TFR element end ridges,” and (b) vertical ridges extending upwardly from side edges of the base portion extending between the opposing ends of the base portion, referred to herein as “TFR element side ridges. ”

It is known that TFR element side ridges may create undesirable effects on a temperature coefficient of resistance (TCR) of the TFR device, for example as described in U.S. Pat. No. 10,818,748. In contrast, TFR element end ridges may be desirable, e.g., to provide an increased contact area between the TFR element and the pair of TFR contacts.

There is a need for improved TFR devices for integrated circuits, and methods of construction. For example, there is a need for TFR devices including a TFR element having reduced or omitted TFR element side ridges, e.g., to reduce unwanted TCR effects discussed above. In addition, there is a need for TFR devices constructed using a reduced number of mask layers, e.g., to reduce fabrication costs. For example, elimination of each mask in a 200 mm wafer process may reduce fabrication costs by about $20 per wafer. There is also a need in some applications for a TFR device that provides a sheet resistance Rₛ of about 1 kΩ/square, for example.

### SUMMARY

Examples of the present disclosure provide improved thin-film resistor (TFR) devices formed in in IC devices, and methods of forming such TFR devices. Some examples provide a TFR device including a TFR element having reduced or omitted TFR element side ridges, and in some examples, while including TFR element end ridges connected to respective TFR contacts.

One aspect provides a method, including forming a first TFR contact and a second TFR contact in a dielectric region, wherein the first and second TFR contacts are spaced apart from each other in a first direction; forming a dielectric barrier layer over the first and second TFR contacts; and removing a region of the dielectric barrier layer to define a dielectric barrier layer opening exposing an area of the dielectric region between the first and second TFR contacts, the dielectric barrier layer opening defining a pair of opposing lateral edges of the dielectric barrier layer extending in the first direction between the first and second TFR contacts. A TFR cavity etch is performed through the dielectric barrier layer opening to define a TFR cavity in the dielectric region, wherein the TFR cavity extends below each of the pair of opposing lateral edges of the dielectric barrier layer to define a respective undercut cavity region of the TFR cavity extending under the dielectric barrier layer near each of the opposing lateral edges of the dielectric barrier layer. A TFR element material is deposited in the TFR cavity to define a TFR element layer including: (a) a TFR element base over an upper surface of the dielectric region, the TFR element base defining a pair of opposing end edges adjacent the first and second TFR contacts, respectively, and a pair of opposing side edges extending between the pair of opposing end edges; and (b) a pair of TFR element end ridges extending upwardly from the pair of opposing end edges of the TFR element base, respectively.

In some examples, the undercut cavity regions of the TFR cavity prevent a formation of vertical ridges of the TFR element material extending upwardly from the opposing side edges of the TFR element base.

In some examples, the TFR cavity etch comprises an isotropic etch. In some examples, the isotropic etch comprises a wet etch with diluted hydrofluoric acid (HF).

In some examples, each respective undercut cavity region of the TFR cavity extends below the dielectric barrier layer in a lateral direction perpendicular to the lateral edges of the dielectric barrier layer by a distance in a range of 2-10 times a vertical thickness of the TFR element layer.

In some examples, the pair of TFR element end ridges includes a first TFR element end ridge conductively coupled to the first TFR contact and a second TFR element end ridge conductively coupled to the second TFR contact.

In some examples, the method includes depositing a TFR cap layer over the TFR element material, and performing a planarization process to remove portions of the TFR cap layer and portions of the TFR element material, wherein after the planarization process: (a) a remaining portion of the TFR element material defines a TFR element conductively connected between the first and second TFR contacts, the TFR element including (a) the TFR element base and (b) the pair of TFR element end ridges extending upwardly from the opposing end edges of the TFR element base, respectively; and (b) a remaining portion of the TFR cap layer defines a TFR cap over the TFR element.

In some examples, the TFR element is free of ridges extending upwardly from the pair of opposing side edges of the TFR element base.

In some examples, the TFR element comprises SiCCr (silicon-silicon carbide-chromium), SiCr (silicon-chromium), NiCr (nickel-chromium), TaN (tantalum nitride), AlNiCr (aluminum-doped nickel-chromium), or TiNiCr (titanium-nickel-chromium).

In some examples, the method includes forming the first and second TFR contacts in the dielectric region using a damascene process.

Another aspect provides a method, including forming a pair of border structures spaced apart from each other in a dielectric region in a first lateral direction; forming a barrier layer over the pair of border structures; removing a region of the barrier layer to define a barrier layer opening exposing an area of the dielectric region between the pair of border structures, the barrier layer opening defining a pair of lateral edges of the barrier layer extending in the first direction between the pair of border structures; perform an etch through the barrier layer opening to define an etched cavity in the dielectric region, wherein the etched cavity includes a respective undercut cavity region extending under the barrier layer, in a second lateral direction perpendicular to the first lateral direction, near each of the pair of lateral edges of the barrier layer; and depositing a conductive material in the etched cavity to define a conductive layer including (a) a laterally extending base having a pair of end edges adjacent the pair of border structures, respectively, and a pair of side edges extending between the pair of end edges and (b) a pair of end ridges extending upwardly from the pair of end edges of the laterally extending base, respectively.

In some examples, the undercut cavity regions of the etched cavity prevent a formation of side ridges of the conductive material extending upwardly from the side edges of the laterally extending base.

In some examples, the etch comprises an isotropic etch. In some examples, the isotropic etch comprises a wet etch with diluted hydrofluoric acid (HF).

In some examples, each respective undercut cavity region of the etched cavity extends below the barrier layer in the second lateral direction by a distance in a range of 2-10 times a vertical thickness of the laterally extending base of the conductive layer.

In some examples, the pair of border structures comprises a pair of conductive structures; and the pair of end ridges of the conductive layer are conductively coupled to the pair of conductive structures, respectively.

In some examples, the method includes depositing a cap layer over the conductive layer; and performing a planarization process to remove portions of the cap layer and portions of the conductive layer; wherein after the planarization process, a remaining portion of the conductive layer defines a conductive element conductively connected between the pair of border structures, the conductive element including (a) the laterally extending base of the conductive layer and (b) the pair of end ridges of the conductive layer extending upwardly from the end edges of the laterally extending base, respectively.

In some examples, the conductive element is free of ridges extending upwardly from the pair of side edges of the laterally extending base of the conductive layer.

Another aspect provides a TFR device, including a first TFR contact and a second TFR contact formed in a dielectric region, wherein the first and second TFR contacts are spaced apart from each other in a first lateral direction; a dielectric barrier layer over the first and second TFR contacts; and a dielectric barrier layer opening in the dielectric barrier layer, the dielectric barrier layer opening defining a pair of opposing lateral edges of the dielectric barrier layer extending in the first direction between the first and second TFR contacts. The TFR device includes an etched cavity in the dielectric region, the etched cavity extending below the dielectric barrier layer near each of the pair of opposing lateral edges of the dielectric barrier layer to define a respective undercut cavity region near each of the opposing lateral edges of the dielectric barrier layer, each undercut cavity region extending under the dielectric barrier layer in a second lateral direction perpendicular to the first lateral direction. A TFR element extends into the etched cavity, and includes: a TFR element base extending over an upper surface of the dielectric region, the TFR element base defining a pair of opposing end edges adjacent the first and second TFR contacts and a pair of opposing side edges extending between the pair of opposing end edges, and a pair of TFR element end ridges extending upwardly from the opposing end edges of TFR element base, respectively.

In some examples, the TFR element is free of ridges extending upwardly from the opposing side edges of the TFR element base.

In some examples, each respective undercut cavity region of the etched cavity extends below the dielectric barrier layer in the second lateral direction by a distance in a range of 2-10 times a vertical thickness of the TFR element base.

In some examples, the TFR element comprises SiCCr (silicon-silicon carbide-chromium), SiCr (silicon-chromium), NiCr (nickel-chromium), TaN (tantalum nitride), AlNiCr (aluminum-doped nickel-chromium), or TiNiCr (titanium-nickel-chromium).

### BRIEF DESCRIPTION OF THE DRAWINGS

Example aspects of the present disclosure are described below in conjunction with the figures, in which:

FIGS. 1A-1C show an example TFR device including a TFR element formed without vertical side ridges;

FIGS. 2A-2C through FIGS. 9A-9C illustrate an example process for forming the example TFR device shown in FIGS. 1A-1C;

FIG. 10 shows a side cross-sectional view illustrating aspects for tuning or optimizing the isotropic etch to form the undercut cavity regions of the TFR cavity; and

FIG. 11 shows a side cross-sectional view illustrating aspects for patterning a photomask opening to provide a resulting dielectric barrier layer having a bias toward overhanging the TFR contacts.

It should be understood that the reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

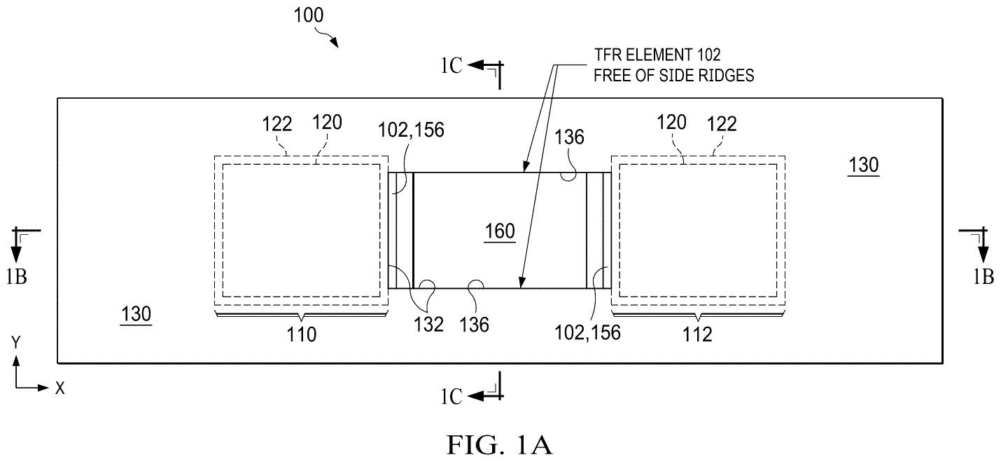

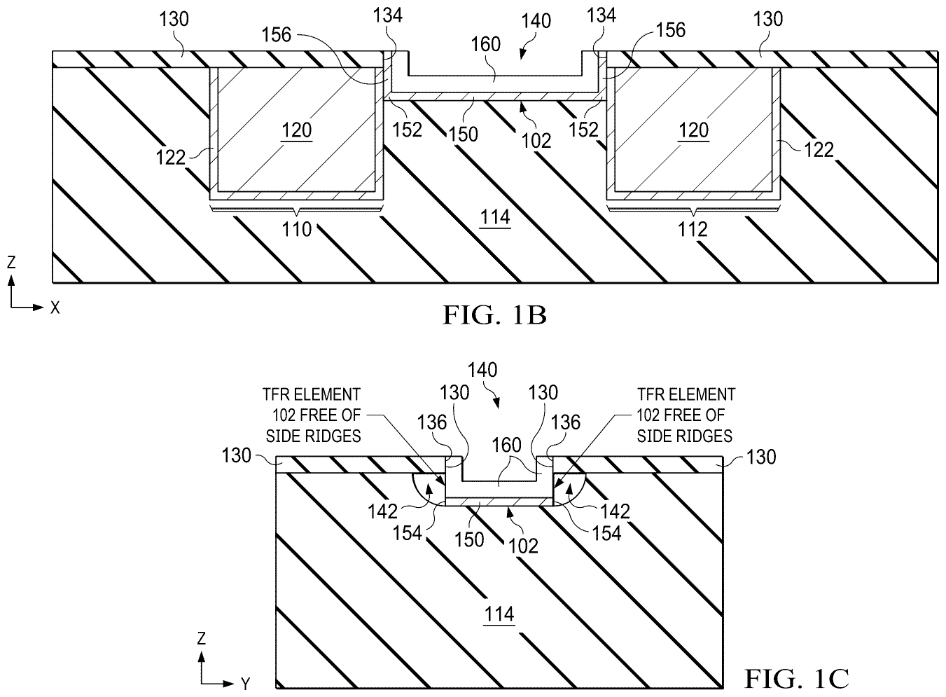

FIGS. 1A-1C show an example TFR device 100 including a TFR element 102 formed without vertical side ridges, as discussed below. FIG. 1A shows a top view of the example TFR device 100, FIG. 1B shows a side cross-sectional view though line 1B-1B shown in FIG. 1A, and FIG. 1C shows another side cross-sectional view though line 1C-1C shown in FIG. 1A.

The example TFR device 100 includes a first TFR contact 110 and a second TFR contact 112 formed in a dielectric region 114. The first and second TFR contacts 110, 112 are spaced apart from each other in a first lateral direction (x-direction). The dielectric region 114 may comprise silicon dioxide (SiO₂), fluorosilicate glass (FSG), or organo-silicate glass (OSG), or other suitable dielectric materials. The dielectric region 114 may be an intermetal dielectric (IMD) region or a pre-metal dielectric (PMD) region, e.g., depending on the depth at which the TFR device 100 is constructed in the relevant IC structure.

Each of the first and second TFR contacts 110, 112 may comprise a conductive structure formed from one or more metal. For example, each TFR contact 110, 112 may comprise a metal fill region 120 (e.g., comprising copper) surrounded on one or more sides by a conductive barrier layer 122 to prevent or inhibit the metal of the metal fill region 120 from diffusing into the neighboring dielectric region 114. In some examples, each TFR contact 110, 112 comprises a copper fill region (metal fill region 120) covered on the bottom and lateral sides by a copper diffusion barrier layer comprising a tantalum (Ta), tantalum nitride (TaN) or a Ta/TaN bilayer (conductive barrier layer 122).

The TFR device 100 may include a dielectric barrier layer 130 formed over the first and second TFR contacts 110, 112. In some examples, the dielectric barrier layer 130 may comprise SiN or SiC, deposited by Plasma Enhanced Chemical Vapor Deposition (PECVD) or other suitable process, with a thickness in the range of 500-1000 Å, for example. The dielectric barrier layer 130 may include a dielectric barrier layer opening 132 defining a pair of lateral end edges 134 of the dielectric barrier layer 130 near the first and second TFR contacts 110, 112 and a pair of opposing lateral side edges 136 of the dielectric barrier layer 130 extending in the first direction (x-direction) between the first and second TFR contacts 110, 112. In some examples, the dielectric barrier layer 130 and conductive barrier layer 122 may fully encapsulate the respective metal fill region 120 of each TFR contact 110, 112, e.g., to prevent metal diffusion or otherwise protect TFR contacts 110, 112.

The TFR device 100 may include an etched cavity 140 (or TFR cavity) in the dielectric region 114, in which the TFR element 102 is formed. The etched cavity 140 may extend below the dielectric barrier layer 130 near each of the pair of opposing lateral side edges 136 of the dielectric barrier layer 130 to define a respective undercut cavity region 142 near each lateral side edge 136 of the dielectric barrier layer 130. Each undercut cavity region extends under the dielectric barrier layer 130 in a second lateral direction (y-direction) perpendicular to the first lateral direction (x-direction).

As shown, the TFR element 102 extends into the etched cavity 140, and includes (a) a TFR element base 150 extending over an upper surface of the dielectric region 114, which TFR element base 150 defines a pair of opposing end edges 152 adjacent the first and second TFR contacts 110, 112 and a pair of opposing side edges 154 extending between the pair of opposing end edges 152, and (b) a pair of TFR element end ridges 156 extending upwardly from the opposing end edges 152 of the TFR element base 150. A TFR cap 160 (e.g., comprising SiN) may be formed over the TFR element 102.

The TFR element end ridges 156 may be conductively connected to the first and second TFR contacts 110, 112, respectively. For example, as shown in FIGS. 1A and 1B, each TFR element end ridges 156 may be formed in contact with one of the first and second TFR contacts 110, 112, in particular in contact with (abutting) the conductive barrier layer 122 on a respective side of the respective TFR contact 110, 112.

As shown, the TFR element 102 may be free of TFR element side ridges, i.e., vertical ridges extending upwardly from the pair of side edges 154 of the TFR element base 150. As a results, the TFR element 102 may have a shape similar to a steel C-channel commonly used in construction. As discussed below, the undercut cavity regions 142 of the etched cavity 140 extending under the dielectric barrier layer 130 near the opposing lateral edges 136 of the dielectric barrier layer 130 may prevent or inhibit the formation of such TFR element side ridges.

It should be understood that the TFR device 100 shown in FIGS. 1A-1C may represent a partially constructed IC device. The fully constructed IC device may include additional interconnect structures and/or other electronic components, e.g., formed above the TFR element 102.

As discussed above, eliminating or reducing the formation of TFR element side ridges may reduce or eliminate unwanted temperature coefficient of resistance (TCR) effects on the operation of the TFR device 100, e.g., as compared with TFR elements including such side ridges.

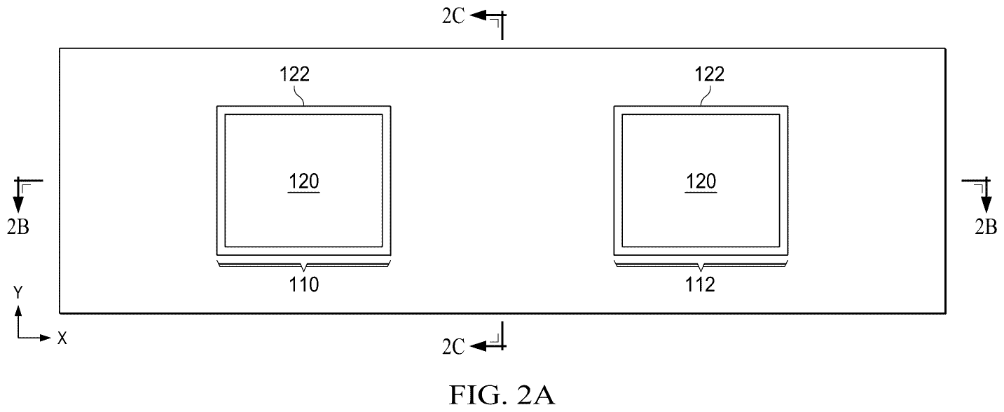

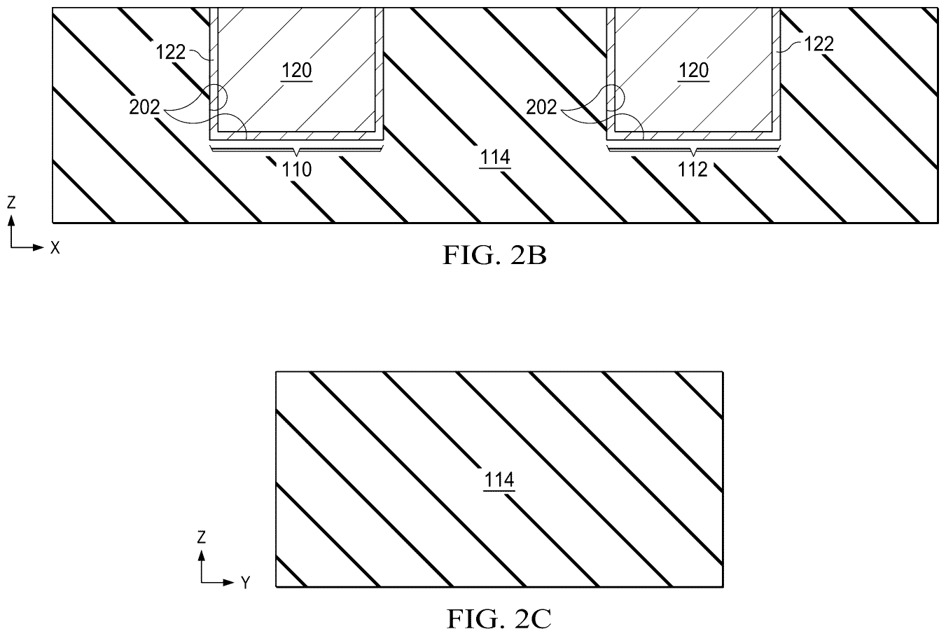

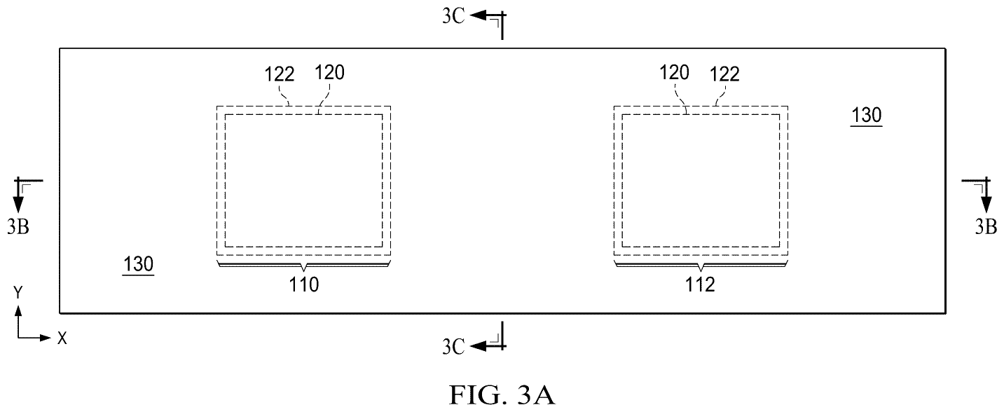

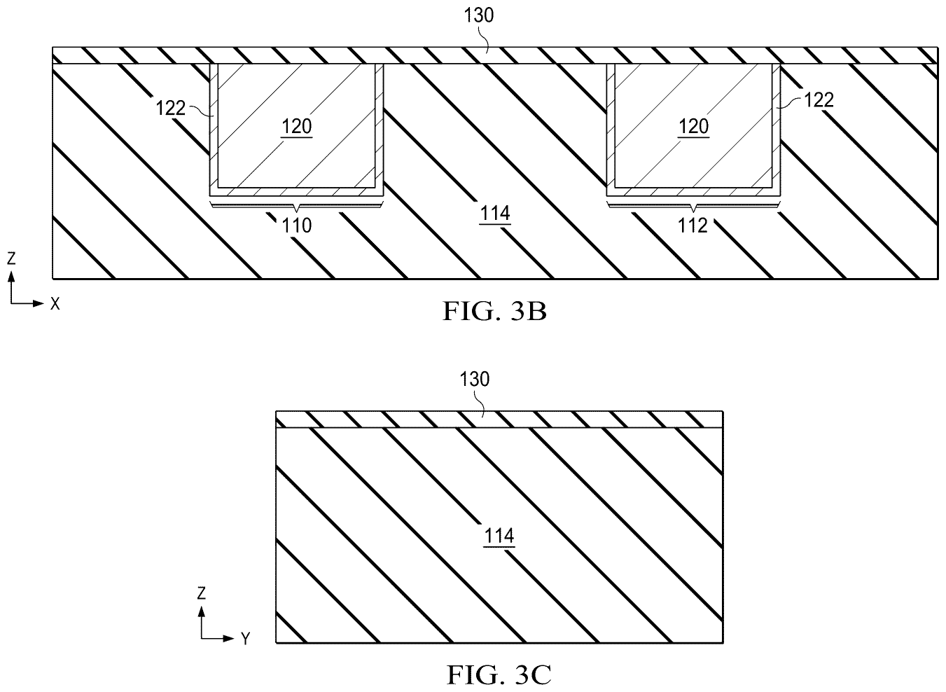

FIGS. 2A-2C through FIGS. 9A-9C illustrate an example process for forming the example TFR device 100 shown in FIGS. 1A-1C. Each set of three figures, i.e., FIGS. 2A-2C, FIGS. 3A-3C, etc., includes a top view and two orthogonal side views, corresponding with the top view and side views shown in FIGS. 1A-1C discussed above. In the illustrated example, the TFR device 100 may be constructed as a module incorporated in a conventional CMOS process flow, e.g., for copper interconnect.

First, as shown in FIGS. 2A-2C, the first and second TFR contacts 110 and 112 are formed in the dielectric region 114 using a damascene process including forming tub openings 202 in the dielectric region 114, depositing the diffusion barrier layer 122 (e.g., a copper diffusion barrier layer, for example Ta, TaN, or a Ta/TaN bi-layer) over the dielectric region 114 and extending down into the tub openings 202, depositing a fill metal over the diffusion barrier layer 122 and extending down into the tub openings 202 (e.g., including performing a copper seed deposition, a copper plating process, and a copper anneal process), and performing a planarization process (e.g., Chemical-Mechanical Polishing or CMP) to remove upper portions of the diffusion barrier layer 122 and fill metal, wherein remaining portions of the fill metal in the tub openings 202 define the metal fill regions 120 of the first and second TFR contacts 110 and 112.

As shown in FIGS. 3A-3C, the dielectric barrier layer 130 is deposited over the structure. In some examples, the dielectric barrier layer 130 may comprise SiN or SiC, which may be deposited by PECVD or other suitable process, to a thickness in the range of 500-1000 Å, for example. The dielectric barrier layer may prevent diffusion (e.g., copper diffusion) from the tops of the metal fill regions 120 of the TFR contacts 110 and 112.

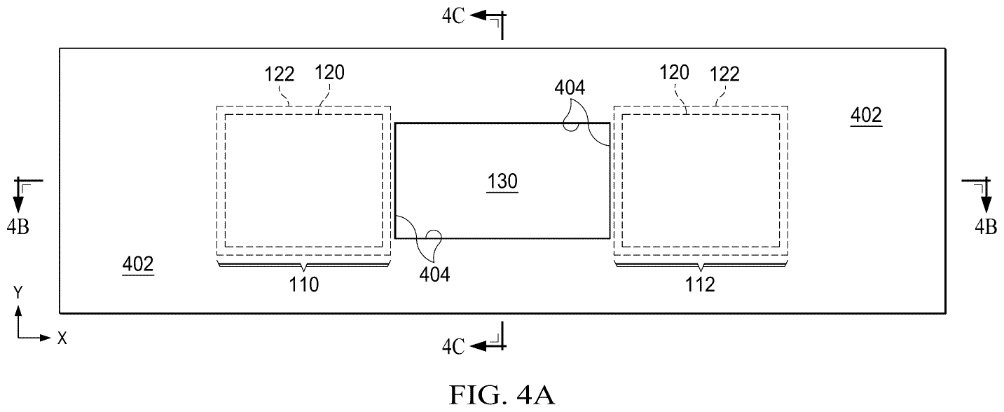

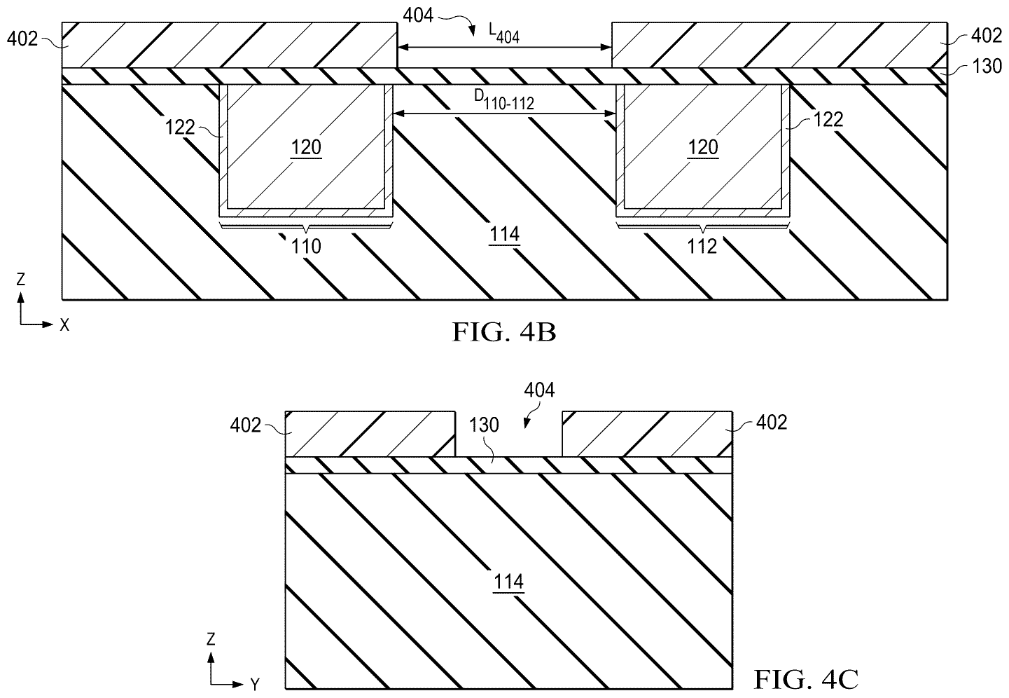

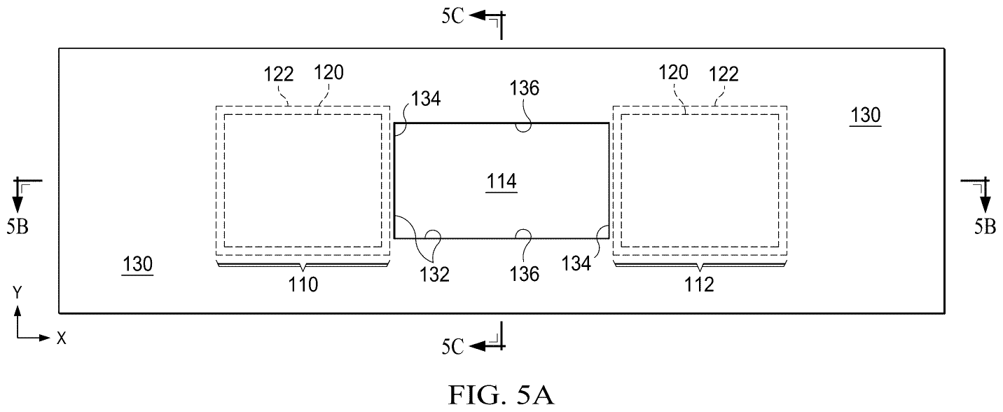

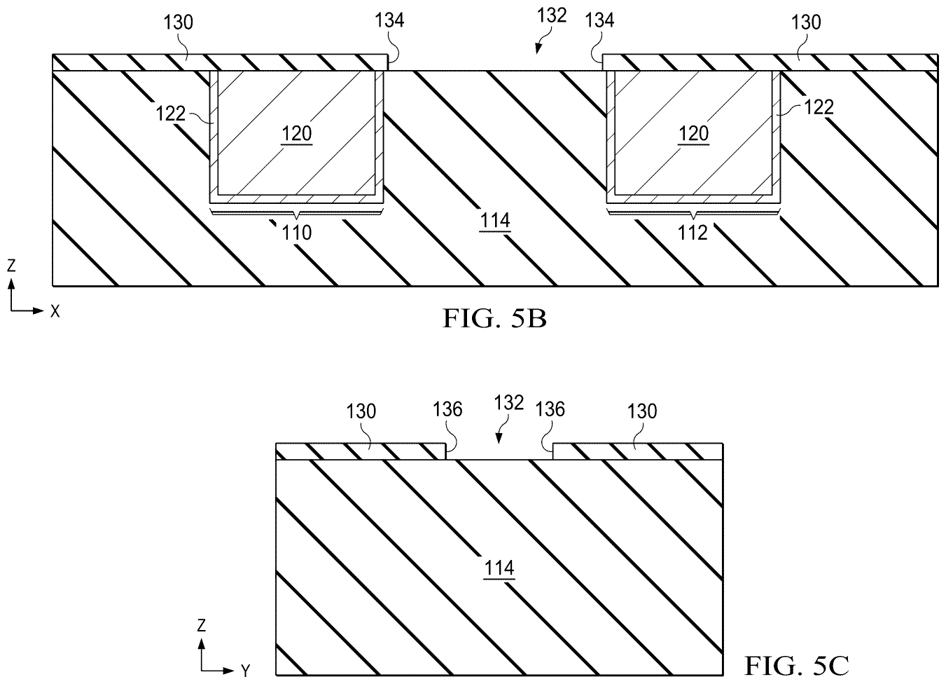

As shown in FIGS. 4A-4C, the dielectric barrier layer opening 132 may be patterned by forming and patterning a photoresist 402 having a photoresist opening 404 corresponding with the dielectric barrier layer opening 132 to be formed between the TFR contacts 110 and 112. In some examples, the photoresist opening 404 may be formed with a smaller length L₄₀₄ in the x-direction (i.e., the direction extending between the TFR contacts 110 and 112) than the x-direction distance of separation D₁₁₀₋₁₁₂ between the TFR contacts 110 and 112, such that after etching the opening 132 in the dielectric barrier layer 130, the dielectric barrier layer 130 may overhang each TFR contacts 110 and 112 in the x-direction (as shown in FIGS. 5A-5C discussed below) to avoid exposure of the TFR contacts 110 and 112 to the environment.

As shown in FIGS. 5A-5C, the dielectric barrier layer opening 132 may be formed by etching the dielectric barrier layer 130 through the photoresist opening 404, e.g., using a plasma etch, after which the remaining photoresist 402 may be removed. The etch may stop on the underlying dielectric region 114. The dielectric barrier layer opening 132 may define a pair of lateral end edges 134 of the dielectric barrier layer 130 near the first and second TFR contacts 110, 112 and a pair of opposing lateral side edges 136 of the dielectric barrier layer 130 extending in the first direction (x-direction) between the TFR contacts 110 and 112. As noted above, in some examples, the lateral end edges 134 of the dielectric barrier layer 130 may overhang the respective TFR contacts 110 and 112 in the x-direction, e.g., to avoid exposing the TFR contacts 110 and 112 to the environment.

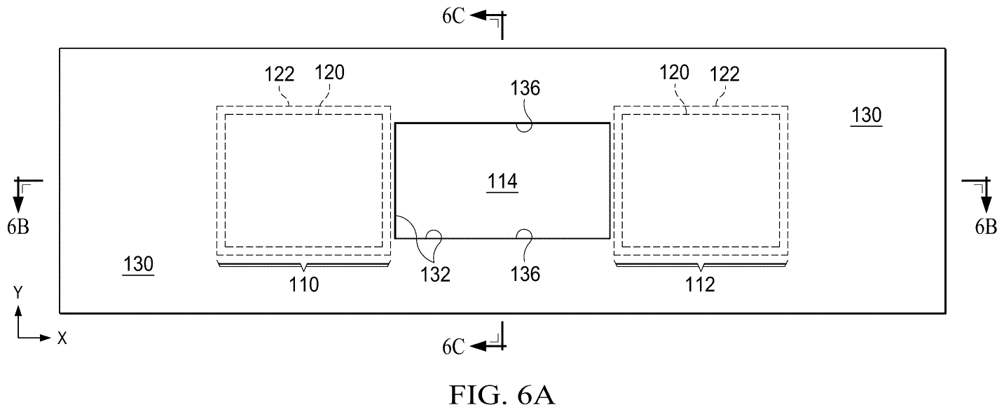

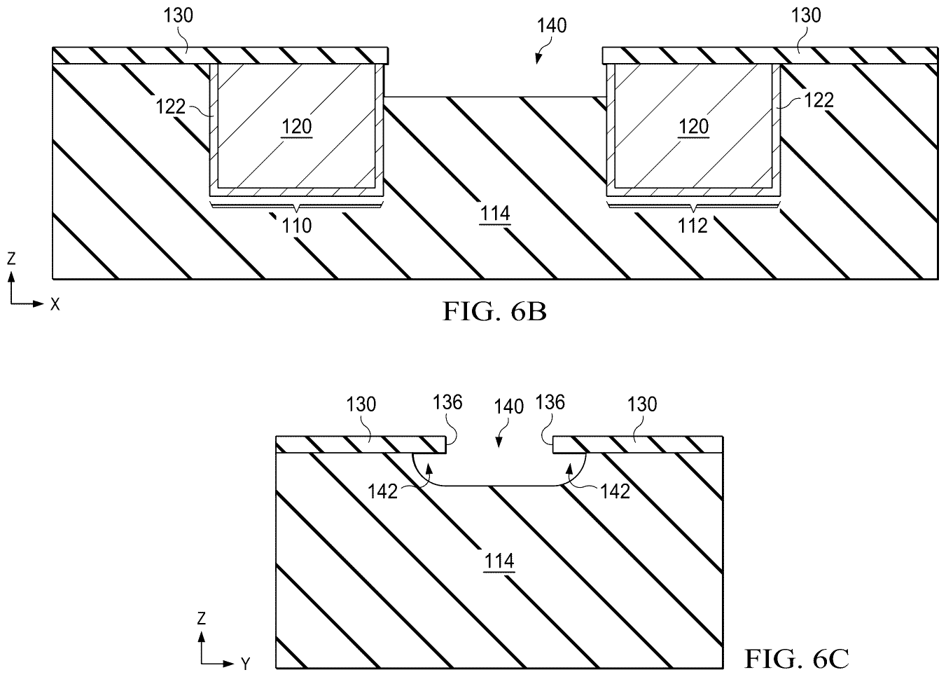

As shown in FIGS. 6A-6C, an isotropic etch (also referred to herein as a TFR cavity etch) may be performed through the dielectric barrier layer opening 132 to form the etched cavity 140 (TFR cavity) in the dielectric region 114. As shown in FIG. 6C, due to the isotropic etch, the etched cavity 140 extends below the dielectric barrier layer 130 near the lateral side edges 136 in the y-direction, to define the undercut cavity regions 142 below each lateral side edge 136 of the dielectric barrier layer 130. Near the TFR contacts 110 and 112, the etch stops on the conductive barrier layer 122, as shown in FIG. 6B.

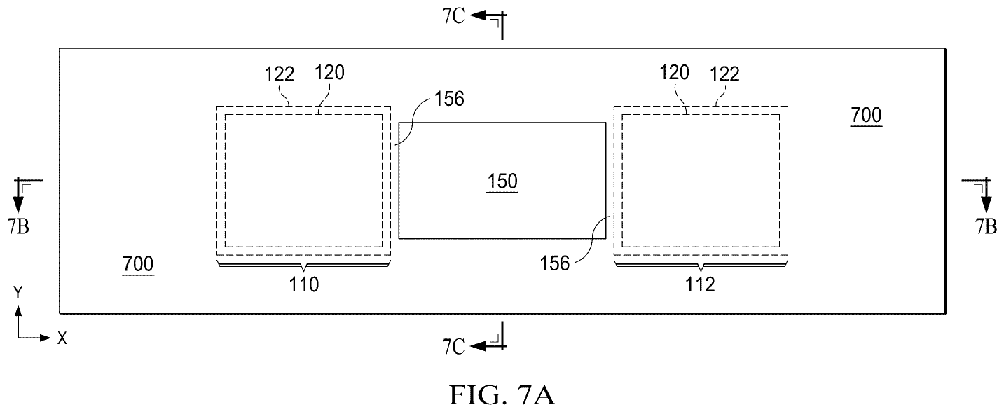

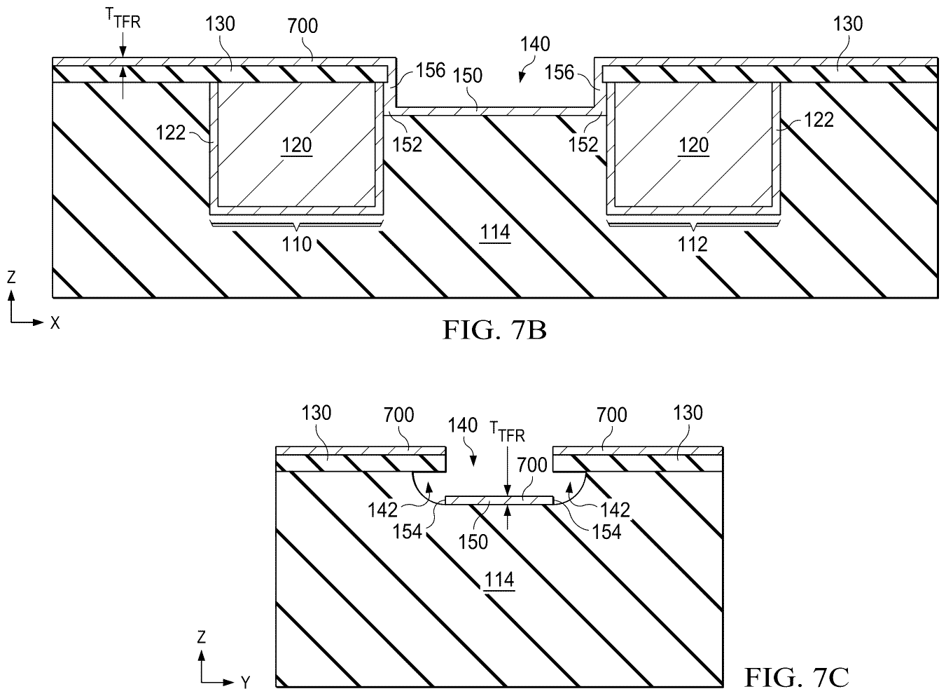

As discussed below with reference to FIGS. 7A-7C, the undercut cavity regions 142 prevent or inhibit formation of vertical ridges of the TFR element material extending upwardly from the side edges 154 of the TFR element base 150. In some examples, the isotropic etch to form the etched cavity 140 comprises a wet etch with diluted hydrofluoric acid (HF).

As shown in FIGS. 7A-7C, a TFR element layer 700 is deposited over the structure and extending down into the etched cavity 140. The TFR element layer 700 defines (a) the TFR element base 150 on an exposed upper surface of the dielectric region 114, which TFR element base 150 defines opposing end edges 152 extending in the y-direction adjacent the first and second TFR contacts 110, 112 and a pair of opposing side edges 154 extending in the x-direction between the opposing end edges 152, and (b) a pair of TFR element end ridges 156 extending upwardly from the opposing end edges 152 of TFR element base 150, respectively.

In some examples, the TFR element layer 700 may comprise silicon carbide chromium (SiCCr), silicon-chromium (SiCr), nickel-chromium (NiCr), aluminum-doped nickel-chromium (AlNiCr), titanium-nickel-chromium (TiNiCr), tantalum nitride (TaN), or other suitable material. In some examples, the TFR element layer 700 may be deposited by Physical Vapor Deposition (PVD) sputter deposition to a thickness in the range of 50-1000 Å (e.g., about 100 Å).

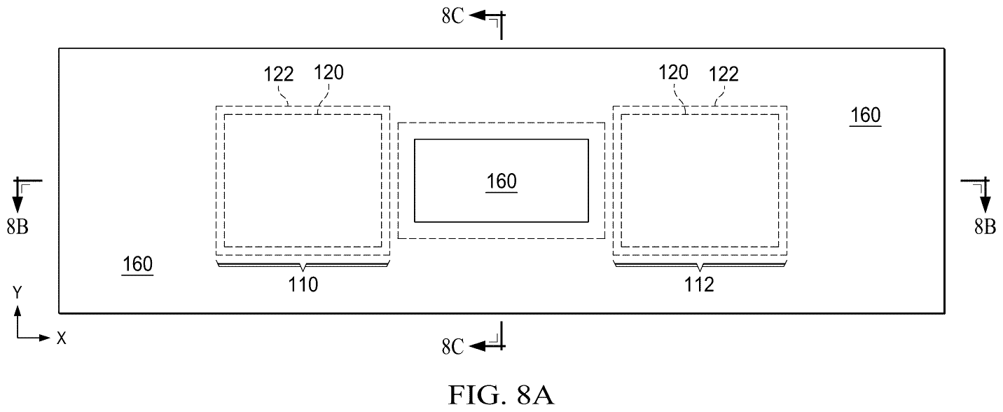

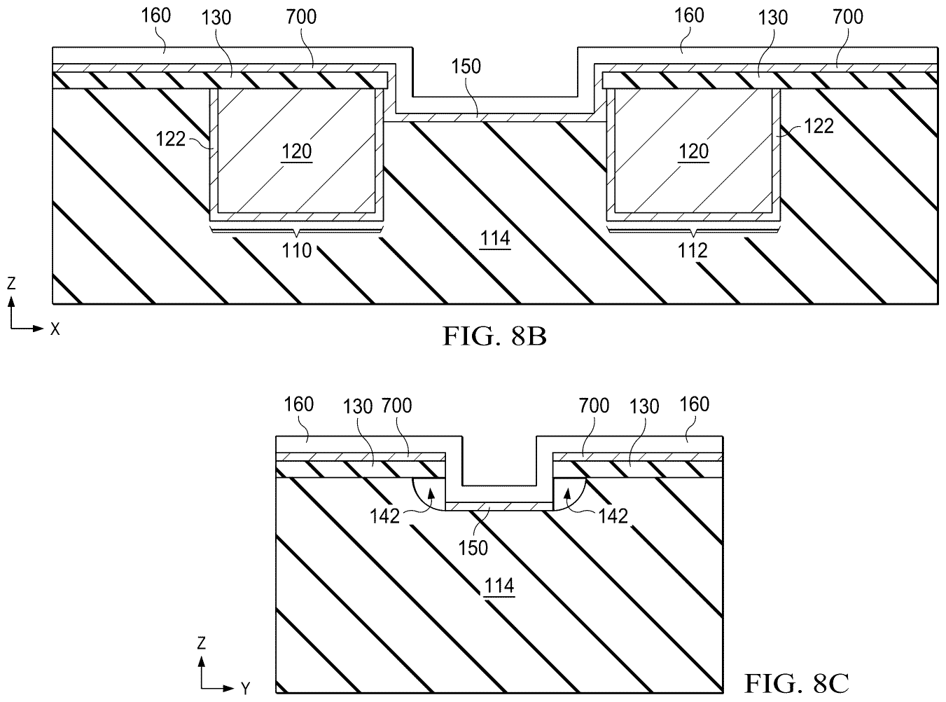

As shown in FIGS. 8A-8C, a TFR cap layer 800 may be deposited over the structure, for example to protect the TFR element 102 being formed (including the TFR element base 150 and TFR element end ridges 156) during a subsequent CMP process. In some examples, the TFR cap layer 800 may comprise SiN deposited by PECVD to a thickness in the range of 200-1000 Å (e.g., about 500 Å). In some examples, the TFR cap layer 800 may be deposited using a High Density Plasma (HDP) process, which may partially fill the undercut cavity regions 142.

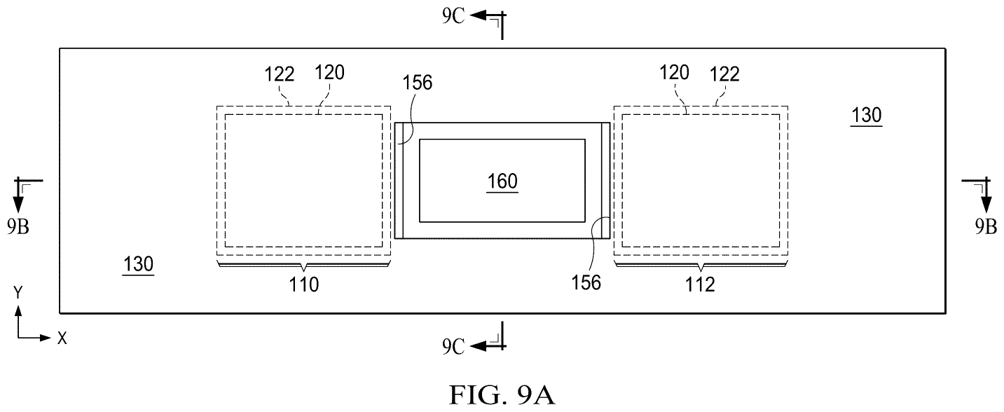

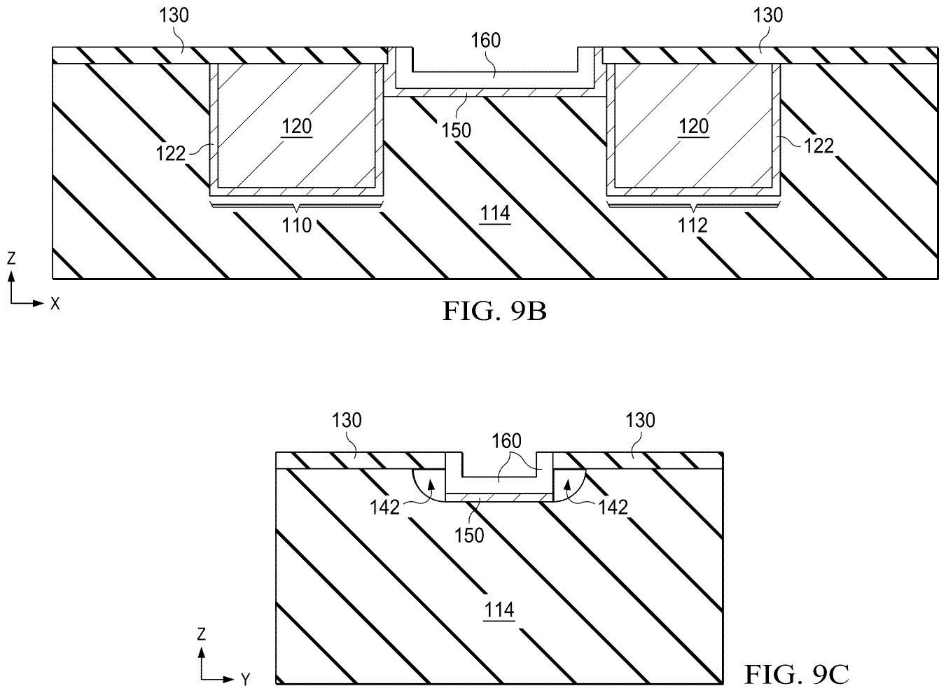

As shown in FIGS. 9A-9C, a planarization process may be performed to remove upper portions of the TFR element layer 700 and upper portions of the TFR cap layer 800. After the planarization process, a remaining portion of the TFR element layer 700 defines the TFR element 102 conductively connected between the first and second TFR contacts 110 and 112, and a remaining portion of the TFR cap layer 800 defines the TFR cap 160 on the TFR element 102. The TFR element 102 includes (a) the TFR element base 150 and (b) the pair of TFR element end ridges 156 extending upwardly from the opposing end edges 152 of the TFR element base 150.

After completion of the TFR device 102 as described above, the background IC fabrication process (e.g., CMOS fabrication process) may be continued, e.g., including construction of additional interconnect structures and/or other electronic components.

In some examples, the method described above may add only one photomask to a background CMOS fabrication process, which may thereby reduce costs relative to other TFR fabrication methods that require multiple additional masks.

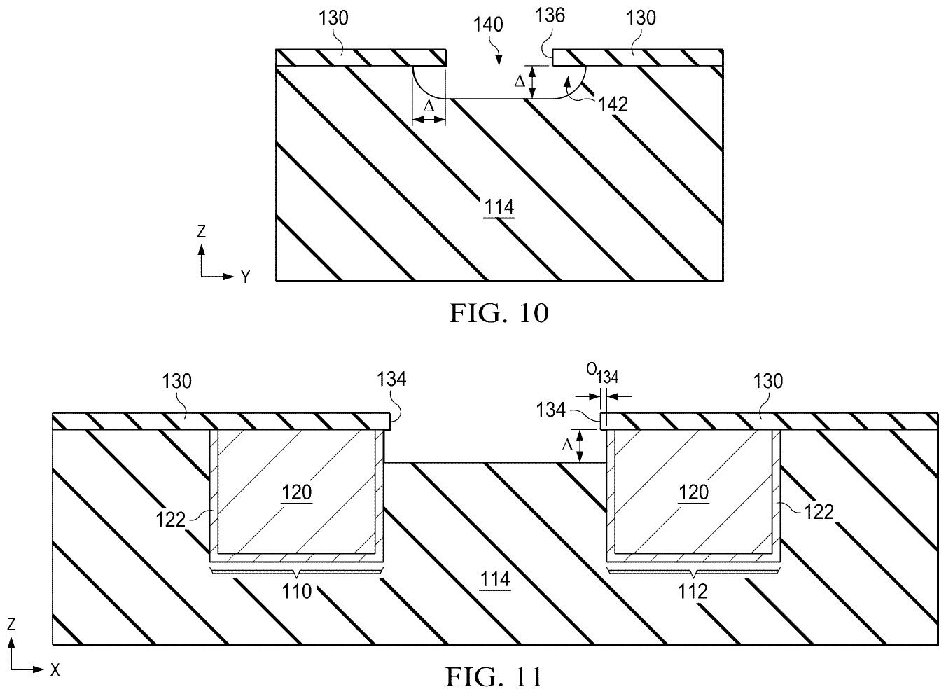

FIG. 10 shows a side cross-sectional view corresponding with the view of FIG. 6C, illustrating aspects for tuning or optimizing the isotropic etch to form the undercut cavity regions 142 of the etched cavity 140. For a typical isotropic etch, the vertical oxide loss and horizontal oxide encroachment (both indicated by Δ) is approximately the same. The parameter Δ can be beneficially selected or optimized based on the thickness of the TFR element layer 700, referred to as T_{TFR} (shown in FIGS. 7A and 7B for references). If Δ is too small, there may be a risk of TFR element side ridge formation, and if Δ is too large, the side edges 152 of the TFR element base 150 may be less defined (“fuzzy”), which may result in a poorly-defined TFR width in the y-direction. Thus, in some examples, the isotropic etch is selected and controlled to provide the parameter Δ in the range of 2-10 times T_{TFR}, which may provide desired results.

FIG. 11 shows a side cross-sectional view corresponding with the view of FIG. 6B, illustrating aspects for aligning the patterning of photomask opening 404 for forming the dielectric barrier layer opening 132. As discussed above, it may be advantageous to pattern the photomask opening 404 such that the resulting dielectric barrier layer opening 132 does not expose either TFR contact 110 or 112, as such exposure may negatively affect a long term reliability of the CMOS transistors.

Ideally, the dielectric barrier layer opening 132 is formed such that the lateral end edges 134 of the remaining dielectric barrier layer 130 are in perfect alignment with the edge of the conductive barrier layer 122 of each TFR contact 110, 112. However, some amount of photo mis-alignment is inherent in manufacturing processes. Thus, it may be advantageous to bias the patterning of the photomask opening 404 toward an overhang of the lateral end edges 134 of the dielectric barrier layer 130 over each TFR contact 110 and 112 in the x-direction, indicated in FIG. 11 at O₁₃₄, to account for a possible photo mis-alignment. A slight overhang of the of the dielectric barrier layer 130 over each TFR contacts 110 and 112 is generally tolerable without significantly impact the formation of the TFR element end ridges 154 on the respective sides of the TFR contacts 110 and 112, assuming the patterned overhang O₁₃₄ is significantly less than the vertical (z-direction) depth of the etch into the dielectric region 114, corresponding with parameter discussed above. In some examples, the photomask opening 404 may be patterned to define an overhang O₁₃₄ of each lateral end edges 134 of the dielectric barrier layer 130 in a range of 0-20 nm.

1. A method, comprising:
forming a first thin film resistor (TFR) contact and a second TFR contact in a dielectric region, wherein the first and second TFR contacts are spaced apart from each other in a first direction;
forming a dielectric barrier layer over the first and second TFR contacts;
removing a region of the dielectric barrier layer to define a dielectric barrier layer opening exposing an area of the dielectric region between the first and second TFR contacts, the dielectric barrier layer opening defining a pair of opposing lateral edges of the dielectric barrier layer extending in the first direction between the first and second TFR contacts;
perform a TFR cavity etch through the dielectric barrier layer opening to define a TFR cavity in the dielectric region, wherein the TFR cavity extends below each of the pair of opposing lateral edges of the dielectric barrier layer to define a respective undercut cavity region of the TFR cavity extending under the dielectric barrier layer near each of the opposing lateral edges of the dielectric barrier layer; and
depositing a TFR element material in the TFR cavity to define a TFR element layer including:
(a) a TFR element base over an upper surface of the dielectric region, the TFR element base defining a pair of opposing end edges adjacent the first and second TFR contacts, respectively, and a pair of opposing side edges extending between the pair of opposing end edges; and
(b) a pair of TFR element end ridges extending upwardly from the pair of opposing end edges of the TFR element base, respectively.

2. The method of claim 1, wherein the undercut cavity regions of the TFR cavity prevent a formation of vertical ridges of the TFR element material extending upwardly from the opposing side edges of the TFR element base.

3. The method of claim 1, wherein the TFR cavity etch comprises an isotropic etch.

4. The method of claim 3, wherein the isotropic etch comprises a wet etch with diluted hydrofluoric acid (HF).

5. The method of claim 1, wherein each respective undercut cavity region of the TFR cavity extends below the dielectric barrier layer in a lateral direction perpendicular to the lateral edges of the dielectric barrier layer by a distance in a range of 2-10 times a vertical thickness of the TFR element layer.

6. The method of claim 1, wherein the pair of TFR element end ridges includes a first TFR element end ridge conductively coupled to the first TFR contact and a second TFR element end ridge conductively coupled to the second TFR contact.

7. The method of claim 1, comprising:
depositing a TFR cap layer over the TFR element material; and
performing a planarization process to remove portions of the TFR cap layer and portions of the TFR element material;
wherein after the planarization process:
a remaining portion of the TFR element material defines a TFR element conductively connected between the first and second TFR contacts, the TFR element including (a) the TFR element base and (b) the pair of TFR element end ridges extending upwardly from the opposing end edges of the TFR element base, respectively; and
a remaining portion of the TFR cap layer defines a TFR cap over the TFR element.

8. The method of claim 7, wherein the TFR element is free of ridges extending upwardly from the pair of opposing side edges of the TFR element base.

9. The method of claim 1, wherein the TFR element comprises SiCCr (silicon-silicon carbide-chromium), SiCr (silicon-chromium), NiCr (nickel-chromium), TaN (tantalum nitride), AlNiCr (aluminum-doped nickel-chromium), or TiNiCr (titanium-nickel-chromium).

10. The method of claim 1, comprising forming the first and second TFR contacts in the dielectric region using a damascene process.

11. A method, comprising:
forming a pair of border structures spaced apart from each other in a dielectric region in a first lateral direction;
forming a barrier layer over the pair of border structures;
removing a region of the barrier layer to define a barrier layer opening exposing an area of the dielectric region between the pair of border structures, the barrier layer opening defining a pair of lateral edges of the barrier layer extending in the first direction between the pair of border structures;
perform an etch through the barrier layer opening to define an etched cavity in the dielectric region, wherein the etched cavity includes a respective undercut cavity region extending under the barrier layer, in a second lateral direction perpendicular to the first lateral direction, near each of the pair of lateral edges of the barrier layer; and
depositing a conductive material in the etched cavity to define a conductive layer including:
(a) a laterally extending base having a pair of end edges adjacent the pair of border structures, respectively, and a pair of side edges extending between the pair of end edges; and
(b) a pair of end ridges extending upwardly from the pair of end edges of the laterally extending base, respectively.

12. The method of claim 11, wherein the undercut cavity regions of the etched cavity prevent a formation of side ridges of the conductive material extending upwardly from the side edges of the laterally extending base.

13. The method of claim 11, wherein the etch comprises an isotropic etch.

14. The method of claim 13, wherein the isotropic etch comprises a wet etch with diluted hydrofluoric acid (HF).

15. The method of claim 11, wherein each respective undercut cavity region of the etched cavity extends below the barrier layer in the second lateral direction by a distance in a range of 2-10 times a vertical thickness of the laterally extending base of the conductive layer.

16. The method of claim 11, wherein:
the pair of border structures comprises a pair of conductive structures;
the pair of end ridges of the conductive layer are conductively coupled to the pair of conductive structures, respectively.

17. The method of claim 11, comprising:
depositing a cap layer over the conductive layer; and
performing a planarization process to remove portions of the cap layer and portions of the conductive layer;
wherein after the planarization process, a remaining portion of the conductive layer defines a conductive element conductively connected between the pair of border structures, the conductive element including (a) the laterally extending base of the conductive layer and (b) the pair of end ridges of the conductive layer extending upwardly from the end edges of the laterally extending base, respectively.

18. The method of claim 17, wherein the conductive element is free of ridges extending upwardly from the pair of side edges of the laterally extending base of the conductive layer.

19. A TFR device, comprising:
a first thin film resistor (TFR) contact and a second TFR contact formed in a dielectric region, wherein the first and second TFR contacts are spaced apart from each other in a first lateral direction;
a dielectric barrier layer over the first and second TFR contacts;
a dielectric barrier layer opening in the dielectric barrier layer, the dielectric barrier layer opening defining a pair of opposing lateral edges of the dielectric barrier layer extending in the first direction between the first and second TFR contacts;
an etched cavity in the dielectric region, the etched cavity extending below the dielectric barrier layer near each of the pair of opposing lateral edges of the dielectric barrier layer to define a respective undercut cavity region near each of the opposing lateral edges of the dielectric barrier layer, each undercut cavity region extending under the dielectric barrier layer in a second lateral direction perpendicular to the first lateral direction; and
a TFR element extending into the etched cavity, the TFR element including:
a TFR element base extending over an upper surface of the dielectric region, the TFR element base defining a pair of opposing end edges adjacent the first and second TFR contacts and a pair of opposing side edges extending between the pair of opposing end edges; and
a pair of TFR element end ridges extending upwardly from the opposing end edges of TFR element base, respectively.

20. The TFR device of claim 19 wherein the TFR element is free of ridges extending upwardly from the opposing side edges of the TFR element base.

21. The TFR device of claim 19, wherein each respective undercut cavity region of the etched cavity extends below the dielectric barrier layer in the second lateral direction by a distance in a range of 2-10 times a vertical thickness of the TFR element base.

22. The TFR device of claim 19, wherein the TFR element comprises SiCCr (silicon-silicon carbide-chromium), SiCr (silicon-chromium), NiCr (nickel-chromium), TaN (tantalum nitride), AlNiCr (aluminum-doped nickel-chromium), or TiNiCr (titanium-nickel-chromium).
